(19) United States
(12) Patent Application Publication
(10) Pub. No.: US 2025/0126969 A1
(43) Pub. Date: Apr. 17, 2025

(54) LIGHT-EMITTING ELEMENT AND DISPLAY DEVICE HAVING THE LIGHT-EMITTING ELEMENT

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 18/910,109

(22) Filed: Oct. 9, 2024

(30) Foreign Application Priority Data
Oct. 17, 2023 (JP) 2023-178577
May 7, 2024 (JP) 2024-075380

(51) Int. Cl. H10K 50/18; H10K 101/10; H10K 101/20

(52) U.S. Cl. CPC H10K 50/181; H10K 2101/10; H10K 2101/20

(57) ABSTRACT

Disclosed is a light-emitting element including an anode, a cathode, and an electroluminescence layer between the anode and the cathode. The electroluminescence layer includes: an electron-blocking layer; a buffer layer over the electron-blocking layer; and an emission layer located over the buffer layer and containing a host material and a first emission material exhibiting thermally activated delayed fluorescence. The buffer layer contains the host material. The emission layer may further include a second emission material. An energy level of a singlet excited state of the second emission material is lower than an energy level of a singlet excited state of the first emission material.

### CROSS-REFERENCE TO RELATED APPLICATIONS

This application claims the benefit of priority to Japanese Patent Application No. 2023-178577, filed on Oct. 17, 2023, and Japanese Patent Application No. 2024-075380, filed on May 7, 2024, the entire contents of which are incorporated herein by reference.

### FIELD

An embodiment of the present invention relates to a light-emitting element and a display device having the light-emitting element.

### BACKGROUND

In recent years, display devices having organic electroluminescence elements (OLEDs) have been widely used. In addition, organic electroluminescence elements exhibiting thermally activated delayed fluorescence or hyper-fluorescence (registered trademark) have attracted much attention because of their extremely high emission efficiency, and tremendous research and development are being conducted (see, for example, Japanese Patent Application Publications No. 2021-048366 and 2020-013695).

### SUMMARY

An embodiment of the present invention is a light-emitting element. The light-emitting element includes an anode, a cathode, and an electroluminescence layer between the anode and the cathode. The electroluminescence layer includes: an electron-blocking layer; a buffer layer over the electron-blocking layer; and an emission layer located over the buffer layer and containing a host material and a first emission material exhibiting thermally activated delayed fluorescence. The buffer layer contains the host material.

An embodiment of the present invention is a display device. The display device includes a red-emissive pixel, a green-emissive pixel, and a blue-emissive pixel. Each of the red-emissive pixel, the green-emissive pixel, and the blue-emissive pixel includes a pixel electrode, an electroluminescence layer over the pixel electrode, and a cathode of the electroluminescence layer, and the electroluminescence layer includes an electron-blocking layer and an emission layer over the electron-blocking layer. The electroluminescence layer of the red-emissive pixel contains a first host material and a first red-emissive emission material exhibiting thermally activated delayed fluorescence. The red-emissive pixel further includes a first buffer layer containing the first host material between the electron-blocking layer and the emission layer. The electron-blocking layer is shared by the red-emissive pixel, the green-emissive pixel, and the blue-emissive pixel and is continuous over the red-emissive pixel, the green-emissive pixel, and the blue-emissive pixel.

### BRIEF DESCRIPTION OF DRAWINGS

FIG. 1 is a schematic cross-sectional view of a light-emitting element according to an embodiment of the present invention.

FIG. 2 is a schematic top view of a display device according to an embodiment of the present invention.

FIG. 3A is a schematic top view of a display device according to an embodiment of the present invention.

FIG. 3B is a schematic top view of a display device according to an embodiment of the present invention.

FIG. 4 is a schematic cross-sectional view of a light-emitting element provided in a pixel of a display device according to an embodiment of the present invention.

FIG. 5 is a schematic cross-sectional view of a display device according to an embodiment of the present invention.

FIG. 6 is a schematic cross-sectional view of a light-emitting element provided in a pixel of a display device according to an embodiment of the present invention.

FIG. 7 is a schematic cross-sectional view of a light-emitting element provided in a pixel of a display device according to an embodiment of the present invention.

FIG. 8 is a schematic cross-sectional view of a light-emitting element provided in a pixel of a display device according to an embodiment of the present invention.

FIG. 9A shows voltage-current density curves of the light-emitting elements fabricated in the Examples.

FIG. 9B is a plot showing a relationship between the thicknesses of the buffer layers and the driving voltages of the light-emitting elements fabricated in the Examples.

FIG. 10A is a plot showing a relationship between the thicknesses of the buffer layers and the current efficiency of the light-emitting elements fabricated in the Examples.

FIG. 10B shows current efficiency-normalized external quantum efficiency curves of the light-emitting elements fabricated in the Examples.

FIG. 11A shows voltage-capacitance curves of the light-emitting elements fabricated in the Examples.

FIG. 11B shows voltage-capacitance curves of the light-emitting elements fabricated in the Examples.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted.

In the specification and the claims, unless specifically stated, when a state is expressed where a structure is arranged “over” another structure, such an expression includes both a case where a structure is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, the mode expressed by this expression includes a mode where the structure is not in contact with the other structure.

### First Embodiment

In the present embodiment, an electroluminescence element (hereinafter simply referred to as “light-emitting element”) 100 according to an embodiment of the present invention is explained.

### 1. Overall Structure

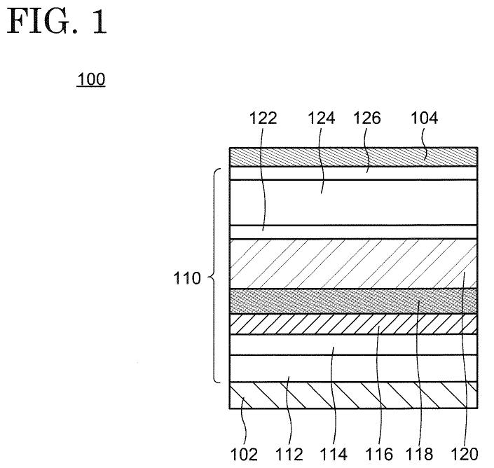

A schematic cross-sectional view of the light-emitting element 100 is shown in FIG. 1. As shown in FIG. 1, the light-emitting element 100 has an anode 102 and a cathode 104 facing each other and includes an electroluminescence layer (hereinafter also referred to as an EL layer) 110 between the anode 102 and the cathode 104. The EL layer 110 is composed of a plurality of functional layers including organic compounds. The EL layer 110 includes an emission layer 120 contributing to light emission as well as an electron-blocking layer 116 and a carrier balance-adjusting layer (hereinafter also referred to as a buffer layer) 118 between the emission layer 120 and the anode 102. The EL layer 110 may also include a hole-injection layer 112, a hole-transporting layer 114, a hole-blocking layer 122, an electron-transporting layer 124, an electron-injection layer 126, and the like. When a potential difference is created between the anode 102 and cathode 104, holes and electrons are injected into the EL layer 110 from the anode 102 and cathode 104, respectively, and these carriers recombine in the emission layer 120. The emission material in the emission layer 120 is excited by the recombination of the holes and the electrons, and the energy released when this excited state returns to the ground state can be extracted as light. Hereinafter, each component is explained.

### 2. Anode and Cathode

The anode 102 is an electrode for injecting holes into the EL layer 110. Since the anode 102 is configured to transmit visible light in the case where the light obtained in the EL layer 110 is extracted through the anode 102, the anode 102 is structured with a conductive oxide transmitting visible light such as indium-tin oxide (ITO) and indium-zinc oxide (IZO). On the other hand, when the light is extracted through the cathode 104, the anode 102 is configured to function as a reflective electrode efficiently reflecting the light. In this case, the anode 102 is configured to include a metal with high reflectivity such as silver and aluminum or an alloy thereof. For example, a structure in which a film containing a metal is sandwiched between films containing a conductive oxide may be applied to the anode 102.

The cathode 104 is an electrode for injecting electrons into the EL layer 110. Since the cathode 104 also functions as a reflecting electrode in the case where the light obtained in the EL layer 110 is extracted through the anode 102, the cathode 104 is configured to include the aforementioned metal or alloy (e.g., an alloy of silver and a metal having a small work function such as magnesium). On the other hand, when the light obtained in the EL layer 110 is extracted through the cathode 104, the cathode 104 is configured to include a conductive oxide transmitting visible light. Alternatively, a metal-containing film having a thickness (e.g., equal to or greater than 5 nm and equal to or less than 20 nm) allowing visible light to pass therethrough may be used as the cathode 104. In the latter case, a film of a conductive oxide transmitting visible light may be provided over the metal-containing film.

### 3. Hole-Injection Layer

The hole-injection layer 112 functions to promote hole injection from the anode 102 to the EL layer 110. A compound to which holes are easily injected, i.e., a (electron-donating) compound which is readily oxidized can be used in the hole-injection layer 112. In other words, a compound with a shallow highest occupied molecular orbital (HOMO) level can be used. For example, an aromatic amine such as a benzidine derivative and a triarylamine, a carbazole derivative, a thiophene derivative, a phthalocyanine derivative such as copper phthalocyanine, and the like can be used. Alternatively, a polymeric material such as polythiophene, polyaniline, and their derivatives can be used, and poly(ethylenedioxythiophene)/poly(styrenesulfonic acid) is represented as an example. A mixture of an electron-donating compound such as the aforementioned aromatic amine and carbazole derivative and an aromatic hydrocarbon with an electron acceptor may be used. The electron acceptor includes a transition metal oxide such as vanadium oxide and molybdenum oxide, a nitrogen-containing heteroaromatic compound, and an aromatic compound with a strong electron-withdrawing group such as a cyano group. The hole-injection layer 112 may have a single layer structure or may be composed of a plurality of layers containing different materials.

### 4. Hole-Transporting Layer

The hole-transporting layer 114 is provided in contact with the hole-injection layer 112. The hole-transporting layer 114 has a function of transporting the holes injected into the hole-injection layer 112 to the emission layer 120, and a material the same as or similar to the material usable in the hole-injection layer 112 can be used. For example, a material with a deeper HOMO level than the hole-injection layer 112, but with a difference therebetween of 0.5 eV or less can be used. Typically, an aromatic amine such as a benzidine derivative may be used. The hole-transporting layer 114 may also have a single layer structure or may be composed of a plurality of layers containing different materials.

### 5. Electron-Blocking Layer

The electron-blocking layer 116 is provided in contact with the hole-transporting layer 114. The electron-blocking layer 116 has a function to confine electrons in the emission layer 120 by preventing the electrons injected from the cathode 104 from passing through the emission layer 120 and being injected into the hole-transporting layer 114 without contributing to recombination in the emission layer 120 as well as a function to prevent energy transfer from the excitation energy obtained in the emission layer 120 to the molecules in the hole-transporting layer 114. These functions prevent a decrease in emission efficiency.

It is preferable to use a material in the electron-blocking layer 116 which has higher or comparable hole transport properties than electron transport properties and which has a shallower lowest unoccupied molecular orbital (LUMO) level and a larger band gap than the molecules in the emission layer 120. Specifically, the difference between the LUMO level of the molecules in the electron-blocking layer 116 and that of the molecules in the emission layer 120 is preferred to be 0.2 eV or greater, 0.3 eV or greater, or 0.5 eV or greater. In addition, the difference between the band gap of the molecules in the electron-blocking layer 116 and that of the molecules in the emission layer 120 is preferred to be 0.2 eV or greater, 0.3 eV or greater, or 0.5 eV or greater. Specifically, an aromatic amine derivative, a carbazole derivative, a 9,10-dihydroacridine derivative, a benzofuran derivative, a benzothiophene derivative, and the like may be used in the electron-blocking layer 116. The electron-blocking layer 116 may also have a single layer structure or may be composed of a plurality of layers containing different materials.

### 6. Buffer Layer

The buffer layer 118 is a functional layer for adjusting the carrier balance of the light-emitting element 100 and is provided in contact with the electron-blocking layer 116. As described below, adjusting the carrier balance using the buffer layer 118 improves the reliability of the light-emitting element 100 without compromising its performance. In addition, when the light-emitting element 100 is applied to a display device, the buffer layer enables the production of the display device at a lower cost.

The buffer layer 118 contains the host material contained in the emission layer 120 described below. In other words, the material contained in the buffer layer 118 is identical to the host material contained in the emission layer 120. Preferably, the buffer layer 118 consists of the host material and is substantially free of other components. The thickness of the buffer layer 118 is relatively small and is equal to or greater than 2.0 nm and equal to or less than 10 nm or equal to or greater than 2.0 nm and equal to or greater than 8.5 nm, for example.

### 7. Emission Layer

The emission layer 120 contains a host material as its main component as well as an emission material responsible for light emission. The volume ratio of the host material to the emission material (emission material/host material) may be, for example, equal to or greater than 0.30 and equal to or less than 0.6. A variety of compounds may be used as the host material, depending on the emission wavelength of the emission material. For example, as the host material, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, a phenanthroline derivative, an aromatic amine derivative, and a carbazole derivative can be used in addition to zinc and aluminum-based metal complexes.

A material exhibiting thermally activated delayed fluorescence (TADF) (thermally activated delayed fluorescent material) is used as the emission material. In a thermally activated delayed fluorescent material, the difference between the triplet and singlet excitation energy levels is small and is, for example, equal to or greater than 5 meV and equal to or less than 20 meV. Therefore, the triplet excited state of the emission material produced by carrier recombination is able to undergo intersystem crossing to the singlet excited state with extremely small thermal energy such as that of room temperature or lower. As a result, the rate of thermal deactivation of the triplet excited state is relatively reduced and radiative deactivation from the singlet excited state is promoted. This mechanism dramatically improves the efficiency of the light-emitting element 100. Due to the emission governed by this mechanism, the thermally activated delayed fluorescent material exhibits emission with a remarkably long lifetime while providing a spectrum similar to that of normal fluorescence. The fluorescence lifetime of the thermally activated delayed fluorescent material is 10⁻⁶ seconds (1 ns) or longer, preferably 10⁻³ seconds (1 μs) or longer.

There is no restriction on the emission color of the thermally activated delayed fluorescence material, and blue-, green-, and red-emissive thermally activated delayed fluorescence materials can be used. Preferably, the thermally activated delayed fluorescence material emits green or red light, and more preferably, emits red light. Here, blue emission refers to emission with a maximum emission peak wavelength in the range equal to or longer than 400 nm and equal to or shorter than 500 nm, green emission refers to emission with a maximum emission peak wavelength in the range equal to or longer than 500 nm and equal to or shorter than 650 nm, and red emission refers to emission with a maximum emission peak wavelength in the range equal to or longer than 650 nm and equal to or shorter than 750 nm.

Examples of the thermally activated delayed fluorescence materials include a fullerene and its derivatives, an acridine derivative such as proflavine, eosin, and the like. A metal-containing porphyrin containing magnesium, zinc, cadmium, tin, platinum, indium, or palladium is also represented. A metal-containing porphyrin includes, for example, a protoporphyrin-tin fluoride complex, a mesoporphyrin-tin fluoride complex, a hematoporphyrin-tin fluoride complex, a coproporphyrin tetramethyl ester-tin fluoride complex, an octaethylporphyrin-tin fluoride complex, an ethioporphyrin-tin fluoride complex, an octaethylporphyrin-platinum chloride complex, and the like.

In addition, a compound in which an electron-donor component and an electron-acceptor component are linked may be used. As the electron-donor component and the electron-acceptor component, a π-electron-excessive heteroaromatic ring and a π-electron-deficient heteroaromatic ring are respectively represented. The basic skeleton of the π-electron-excessive heteroaromatic ring includes a pyridine skeleton, a diazine skeleton, a triazine skeleton, and the like. The basic skeleton of the π-electron-deficient heteroaromatic ring includes an acridine skeleton, a phenoxazine skeleton, a phenothiazine skeleton, a furan skeleton, a thiophene skeleton, a pyrrole skeleton, and the like. As such compounds, 2-(biphenyl-4-yl)-4,6-bis(12-phenylindolo [2,3-a]carbazole-11-yl)-1,3,5-triazine, 9-(4,6-diphenyl-1,3,5-triazine-2-yl)-9′-phenyl-9H,9′H-3,3′-bicarbazole, 9-[4-(4,6-diphenyl-1,3,5-triazine-2-yl)phenyl]-9′-phenyl-9H,9′H-3,3-biucarbazole, 2-[4-(10H-phenoxazin-10-yl)phenyl]-4,6-diphenyl-1,3,5-triazine, and the like are exemplified.

The emission layer 120 may further include, as the emission material, a fluorescent material (hereinafter also referred to as a second emission material) capable of receiving the singlet excited energy of the thermally activated delayed fluorescence material and forming a singlet excited state in addition to the thermally activated delayed fluorescence material. The second emission material is selected so that the energy level of its singlet excited state is lower than that of the thermally activated delayed fluorescent material, i.e., its band gap is smaller than that of the thermally activated delayed fluorescent material. The second emission material does not exhibit thermally activated delayed fluorescence in the light-emitting element 100 and thus exhibits a relatively short fluorescence lifetime (e.g., equal to or longer than 1 ps and equal to or shorter than 1 ns). Specifically, a fluorescent material such as a coumarin derivative, a pyran derivative, a quinacridone derivative, a tetracene derivative, a pyrene derivative, an anthracene derivative, and a pyran derivative are exemplified. In general, the emission spectrum exhibited by thermally activated delayed fluorescent materials is broad and has low color purity. In contrast, since the fluorescent materials described above provide an emission spectrum with a relatively narrow half width, they are capable of emitting light with high color purity. Therefore, further addition of the second emission material to the emission layer 120 enables the production of the light-emitting element 100 with excellent color purity in addition to high emission efficiency resulting from the thermally activated delayed fluorescence material.

### 8. Hole-Blocking Layer

The hole-blocking layer 122 has a function to confine the holes injected from the anode 102 within the emission layer 120 by preventing the holes from passing through the emission layer 120 and being injected into the electron-transporting layer 124 without contributing to recombination as well as a function to prevent the excitation energy obtained in the emission layer 120 from being transferred to the molecules in the electron-transporting layer 124. This mechanism prevents a decrease in emission efficiency.

For the hole-blocking layer 122, it is preferable to use a material having higher or comparable electron-transporting properties than hole-transporting properties as well as a deeper HOMO level and larger band gap than the molecules in the emission layer 120. Specifically, the difference between the HOMO level of the molecules in the hole-blocking layer 122 and that of the molecules in the emission layer 120 is preferred to be 0.2 eV or greater, 0.3 eV or greater, or 0.5 eV or greater. The difference between the band gap of the molecules in the hole-blocking layer 122 and that of the molecules in the emission layer 120 is also preferred to be 0.2 eV or greater, 0.3 eV or greater, or 0.5 eV or greater. Specifically, a phenanthroline derivative, an oxadiazole derivative, a triazole derivative, a metal complex having a relatively large band gaps (e.g., 2.8 eV or higher) such as bis(2-methyl-8-quinolinolato) (4-hydroxy-biphenylyl)aluminum, and the like are represented. The hole-blocking layer 122 may also have a single layer structure or may be composed of a plurality of layers containing different materials.

### 9. Electron-Transporting Layer

The electron-transporting layer 124 functions to transport the electrons injected from the cathode 104 via the electron-injection layer 126 to the emission layer 120. A readily reduced (electron-accepting) compound can be used for the electron-transporting layer 124. In other words, a compound with a shallow LUMO level may be used. For example, a metal complex containing a ligand having benzoquinolinol as the basic skeleton such as tris(8-quinolinolato)aluminum and tris(4-methyl-8-quinolinolato)aluminum, a metal complex containing a ligand having oxadiazole or thiazole as the basic skeleton, and the like are represented. In addition to these metal complexes, a compound with an electron-deficient heteroaromatic ring such as an oxadiazole derivative, a thiazole derivative, a triazole derivative, and a phenanthroline derivative may be used. The electron-transporting layer 124 may also have a single layer structure or may be composed of a plurality of layers containing different materials.

10. Electron-Injection layer

For the electron-injection layer 126, a compound promoting electron injection from the cathode 104 to the electron-transporting layer 124 can be used. For example, a mixture of a compound which can be used for the electron-transporting layer 124 and an electron donor such as lithium and magnesium may be used. Alternatively, an inorganic compound such as lithium fluoride and calcium fluoride may be used.

As described above, the buffer layer 118 containing or consisting of the host material is provided between the emission layer 120 containing the host material and the thermally activated delayed fluorescent material and the electron-blocking layer 116 in the light-emitting element 100. As demonstrated in the Examples, this configuration allows the proper carrier balance of the light-emitting element 100 to be maintained without heavily relying on the material of the electron-blocking layer 116. As a result, the design freedom of the display device including the light-emitting element 100 is increased. As described below, such characteristics contribute to the reduction of the manufacturing cost of display devices. In addition, the aforementioned configuration is able to improve the emission lifetime (i.e., reliability) of the light-emitting element 100 without compromising the characteristics of the light-emitting element 100, thereby providing a highly reliable display device at a low cost.

### Second Embodiment

In the present embodiment, a display device 200 including the light-emitting element 100 described in the First Embodiment is explained. An explanation of the structure the same as or similar to that described in the First Embodiment may be omitted.

### 1. Overall Structure

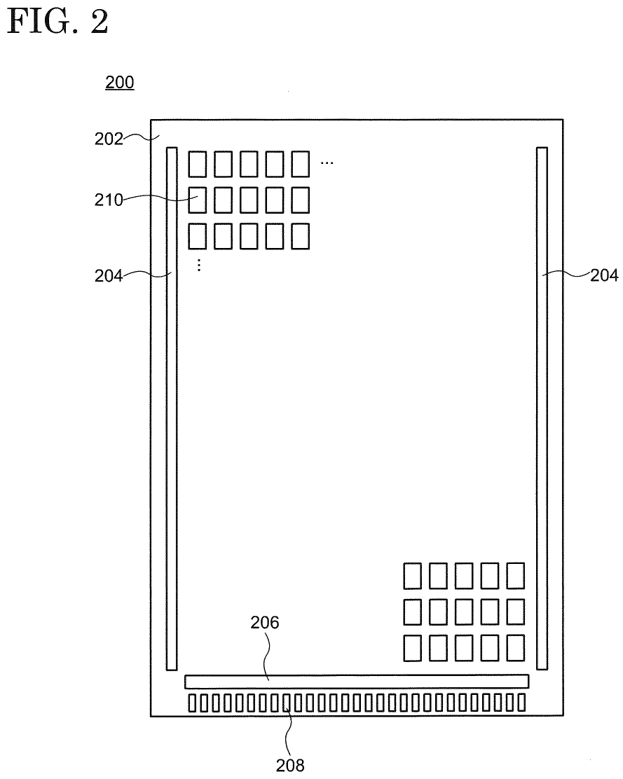

A schematic top view of the display device 200 is shown in FIG. 2. As shown in FIG. 2, the display device 200 has a substrate 202 over which a variety of patterned insulating films, semiconductor films, and conductor films is stacked. Appropriate stacking of these films leads to the formation of a plurality of pixels 210, driver circuits for driving the pixels 210 (scanning-line driver circuits 204 and a signal-line driver circuit 206), and the like over the substrate 202. A counter substrate which is not illustrated in FIG. 2 is provided over the pixels 210, the scanning-line driver circuits 204, and the signal-line driver circuit 206. The substrate 202 and the counter substrate are secured by an adhesive such as a sealant, by which the pixels 210, the scanning-line driver circuits 204, and the signal-line driver circuit 206 are sealed and protected. A plurality of terminals 208 formed with a conductive film is provided over the substrate 202, and the terminals 208 are electrically connected to an external circuit which is not illustrated via a connector such as a flexible printed circuit (FPC) board. A variety of signals and power for displaying images are supplied from the external circuit to the scanning-line driver circuits 204 and the signal-line driver circuit 206 through the terminals 208. Note that either or both of the scanning-line driver circuits 204 and the signal-line driver circuit 206 need not be formed directly over the substrate 202, and a driver circuit formed over a substrate different from the substrate 202 (such as a semiconductor substrate) may be mounted over the substrate 202 or the connector.

In each of the pixels 210, a pixel circuit is formed, and one of the light-emitting elements giving the three primary colors (i.e., a red-emissive light-emitting element, a green-emissive light-emitting element, and a blue-emissive light-emitting element) is further arranged. Signals to drive the pixel circuits are generated by the scanning-line driver circuits 204 and the signal-line driver circuit 206 on the basis of various signals supplied from the external circuits, by which the light-emitting elements connected to the pixel circuits emit light to allow each of the pixels 210 to function as the smallest unit providing color information. As a result, full-color display can be performed. Here, a red-emissive light-emitting element, a green-emissive light-emitting element, and a blue-emissive light-emitting element are, for example, elements respectively exhibiting emission peak wavelengths in the range equal to or longer than 650 nm and equal to or shorter than 750 nm, equal to or longer than 500 nm and equal to or shorter than 650 nm, and equal to or longer than 400 nm and equal to or shorter than 500 nm.

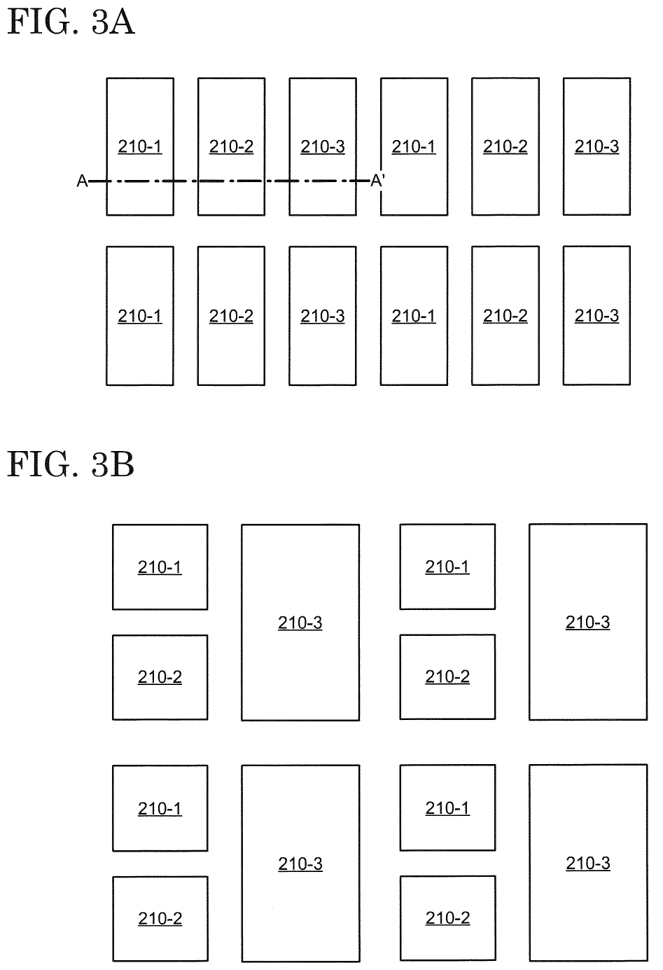

There is no restriction on the arrangement of the pixels 210. For example, the stripe arrangement may be employed in which the red-, green-, and blue-emissive pixels 210-1, 210-2, and 210-3 respectively providing red, green, and blue light are arranged sequentially in the line direction, and the pixels 210 providing the same emission color are arranged in the same row as shown in FIG. 3A. Alternatively, although not illustrated, in addition to the mosaic arrangement in which the red-emissive pixel 210-1, the green-emissive pixel 210-2, and the blue-emissive pixel 210-3 are sequentially arranged in both the row and column directions, a variety of arrangements such as the delta arrangement and the pentile arrangement may be employed. Alternatively, the plurality of pixels 210 may be arranged so that one or more red-emissive pixels 210-1 and one or more green-emissive pixels 210-2 are sandwiched between adjacent blue-emissive pixels 210-3 as shown in FIG. 3B. In this arrangement, the plurality of pixels 210 may be arranged so that the blue-emissive pixel 210-3 in which the blue-emissive light-emitting element with the lowest emission efficiency is arranged has a larger area than the other pixels 210, by which the burden on the blue-emissive light-emitting element is reduced and the reliability of the display device 200 can be improved.

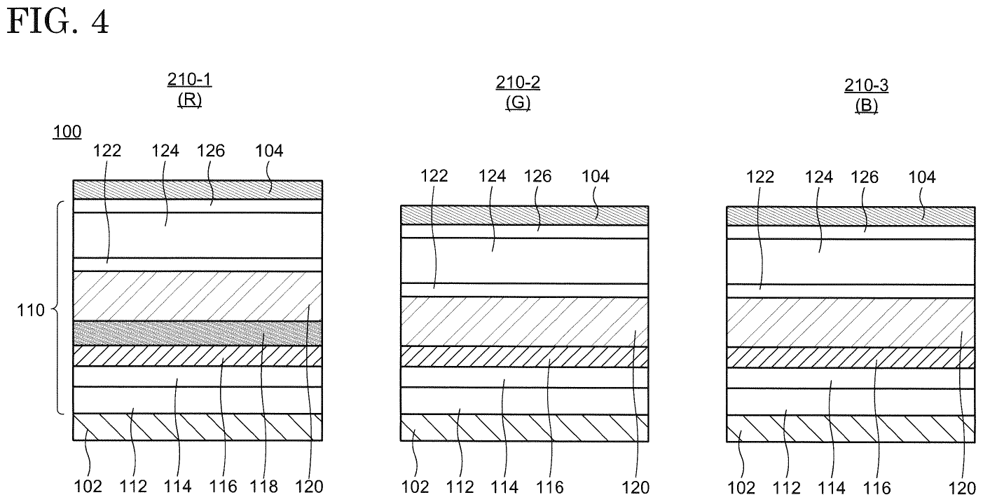

At least one of the red-emissive pixel 210-1, the green-emissive pixel 210-2, and the blue-emissive pixel 210-3 is arranged with the light-emitting element 100 described in the First Embodiment. For example, the light-emitting element 100 may be arranged in the red-emissive pixel 210-1, where light-emitting elements with a different structure than the light-emitting element 100 may be arranged in the green-emissive pixel 210-2 and the blue-emissive pixel 210-3 as shown in FIG. 4. For example, a light-emitting element without the buffer layer 118 may be arranged in the green-emissive pixel 210-2 and the blue-emissive pixel 210-3. Although the electron-blocking layer 116 may also be provided in the green-emissive pixel 210-2 and the blue-emissive pixel 210-3 in this case, the emission layer 120 is in electrical and physical contact with the electron-blocking layer 116 in the green-emissive pixel 210-2 and the blue-emissive pixel 210-3. Alternatively, a light-emitting element containing a fluorescent material (which does not exhibit thermally activated delayed fluorescence) or a phosphorescent material may be placed in the emission layer 120 of the green-emissive pixel 210-2 and the blue-emissive pixel 210-3.

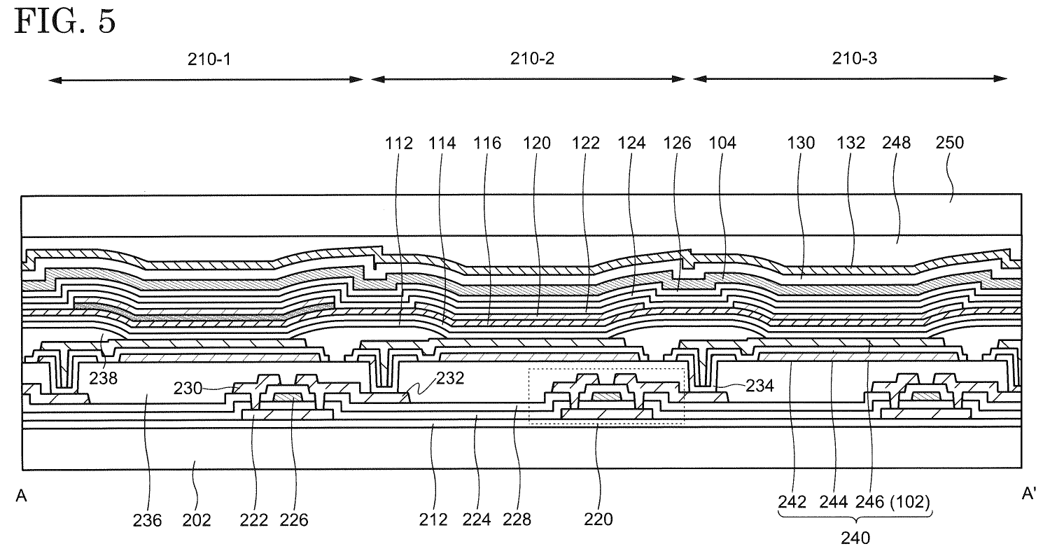

A schematic view of a cross section along the chain line A-A′ in FIG. 3A is shown in FIG. 5. In FIG. 5, the cross section including the continuously arranged red-emissive pixel 210-1, green-emissive pixel 210-2, and blue-emissive pixel 210-3 are schematically illustrated. The configuration of the pixel circuit formed in each of the pixels 210 may be arbitrarily determined, and any known configuration may be applied. In the example shown in FIG. 5, one transistor 220 and a capacitor element (auxiliary capacitor element) 240 connected to the transistor 220 are shown as part of the elements structuring the pixel circuit. Furthermore, a light-emitting element connected to the pixel circuit is provided in each pixel 210. In the example shown in FIG. 5, the combination shown in FIG. 4 is applied. That is, the light-emitting element 100 is arranged in the red-emissive pixel 210-1, and the light-emitting elements without the buffer layer 118 are arranged in the green-emissive pixel 210-2 and the blue-emissive pixel 210-3. Although an example is demonstrated here in which the light from the emission layers 120 is extracted through the counter substrate 250 in all of the light-emitting elements, the display device 200 may be configured so that the light from the emission layers 120 is extracted through the substrate 202.

### 2. Substrate and Counter Substrate

The substrate 202 and the counter substrate 250 are provided to give physical strength to the display device 200 and to protect the plurality of pixels 210, the scanning-line driver circuits 204, and the signal-line driver circuit 206. The substrate 202 and the counter substrate 250 may be an inorganic material-containing substrate such as a crystalline semiconductor substrate, a glass substrate, and a quartz substrate or may contain a polymer such as a polyimide, a polyamide, and a polycarbonate. The substrate 202 and the counter substrate 250 may or may not be flexible. In the former case, the substrate 202 and/or the counter substrate 250 may be sufficiently flexible to be elastically deformed or highly flexible enough to be plastically deformed. When the emission from the light-emitting elements is extracted through the counter substrate 250, at least the counter substrate 250 is configured to transmit visible light. Conversely, when the emission from the light-emitting elements is extracted through the substrate 202, at least the substrate 202 is configured to transmit visible light.

### 3. Pixel Circuit

As described above, since a known configuration may be applied as the pixel circuit, a detailed description is omitted. In the example shown in FIG. 5, the transistor 220 functioning as a driving transistor is provided over the substrate 202. The transistor 220 may be provided directly over the substrate 202 or may be formed over the substrate 202 through an undercoat 212 which prevents the diffusion of impurities contained in the substrate 202. The transistor 220 shown in FIG. 5 is composed of a semiconductor film 222, a gate insulating film 224 over the semiconductor film 222, a gate electrode 226 over the gate insulating film 224, an interlayer insulating film 228 over the gate electrode 226, and a pair of terminals 230 and 232 disposed over the interlayer insulating film 228 and electrically connected to the semiconductor film 222. Although the transistor 220 shown here is a top-gate type transistor, there is no restriction on the structure of the transistor 220, and a bottom-gate type transistor or a transistor having gate electrodes over and under the semiconductor film may be used as the transistor 220.

A leveling film 236 is provided over the transistor 220 to absorb unevenness caused by the elements such as the transistor 220 included in the pixel circuit and to provide a flat surface. The capacitor electrode 242, a capacitor insulating film 244 over the capacitor electrode 242, and a pixel electrode 246 may be arranged over the leveling film 236, and the capacitor element 240 can be fabricated by these components. Here, the pixel electrode 246 functions as the anode 102 of the light-emitting element 100. An opening is provided in the leveling film 236 to expose the terminal 232, and the pixel electrode 246 is electrically connected to the terminal 232 at this opening either directly or via a connecting electrode 234 covering this opening. A partition wall 238, which is an insulating film, is provided to cover the edge of the pixel electrode 246, and the EL layer 110 is arranged to cover the pixel electrode 246 and the partition wall 238. This structure electrically insulates adjacent light-emitting elements 100 and prevents the EL layer 110 from being disconnected by the edge of the pixel electrode 246. Note that, in the example shown in FIG. 5, the pixel electrode 246 is shared by the light-emitting element 100 and the capacitor element 240.

### 4. Light-Emitting Element

As described above, the light-emitting element 100 is arranged in the red-emissive pixel 210-1, and the light-emitting elements without the buffer layer 118 are arranged in the green-emissive pixel 210-2 and the blue-emissive pixel 210-3. Therefore, all or part of the functional layers other than the emission layer 120 and the buffer layer 118 may be provided continuously over all of the pixels 210 so as to be shared by all of the pixels 210. For example, the electron-blocking layer 116 may be formed so as to be shared by all of the pixels 210 and to be continuous over all of the pixels 210 as shown in FIG. 5. As shown in FIG. 5, in addition to the electron-blocking layer 116, the hole-injection layer 112, the hole-transporting layer 114, the hole-blocking layer 122, the electron-transporting layer 124, the electron-injection layer 126, and the cathode 104 may also be provided so as to be shared by all of the pixels 210 and to be provided continuously over all of the pixels 210.

Generally, each functional layer structuring the EL layer 110 is formed using an evaporation method. Therefore, metal masks are used to selectively arrange the functional layers in predetermined areas, and an increase in the number of metal masks directly leads to an increase in the manufacturing cost of display devices. However, all or part of the functional layers other than the emission layer 120 and the buffer layer 118 may be provided continuously over all of the pixels 210 so as to be shared by all of the pixels 210 in the display device 200. Thus, for example, the electron-blocking layer 116 can be formed over all of the pixels 210 using a single metal mask, and pixel-by-pixel deposition using a plurality of metal masks is not required. This feature prevents an increase in the manufacturing cost of display devices and allows display devices to be provided at a lower cost.

### 5. Other Component

As an optional component, one or a plurality of cap layers 130 may be provided over the cathode 104 to resonate the light extracted from the cathode 104 to improve color purity and luminance in the frontal direction. In addition, a protective film 132 may be disposed over the light-emitting elements to prevent impurities such as water and oxygen from entering the EL layer 110. The protective film 132 may be composed of, for example, a film containing silicon nitride, a film containing a polymer such as an acrylic resin and an epoxy resin, or a stack thereof.

### 6. Modified Examples

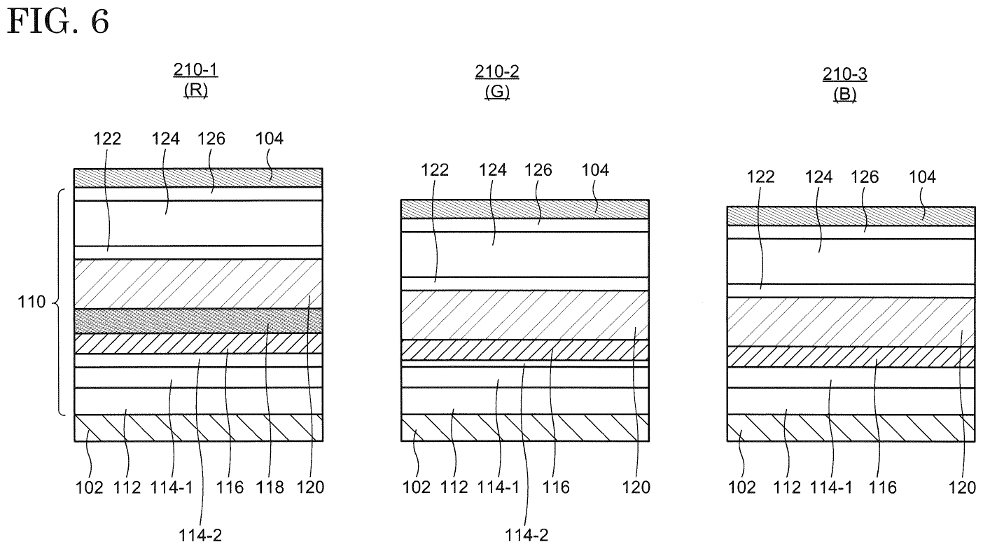

Although the configuration of the hole-transporting layer 114 (number of stacked layers and/or thickness) is the same in all of the pixels 210 in the example shown in FIG. 5, the configuration of the hole-transporting layer 114 may differ between the pixels 210. For example, the number of stacked layers and/or thickness of the hole-transporting layer 114 may differ between the red-emissive pixel 210-1, the green-emissive pixel 210-2, and the blue-emissive pixel 210-3 as shown in FIG. 6. Preferably, the pixels 210 are configured so as to have a larger number of stacked layers and/or thickness of the hole-transporting layer 114 in the pixel 210 providing a longer wavelength. This structure allows the formation of a more effective resonator structure using the EL layer 110. For example, a first hole-transporting layer 114-1 may be continuously formed over all of the pixels 210, and a second hole-transporting layer 114-2 may be further formed over the first hole-transporting layer 114-2 in the red-emissive pixel 210-1 and the green-emissive pixel 210-2. At this time, the pixels 210 may be configured so that the thickness of the second hole-transporting layer 114-2 of the red-emissive pixel 210-1 is larger than that of the green-emissive pixel 210-2. Although not illustrated, the number of stacked layers of the hole-transporting layer 114 may be varied for each pixel 210.

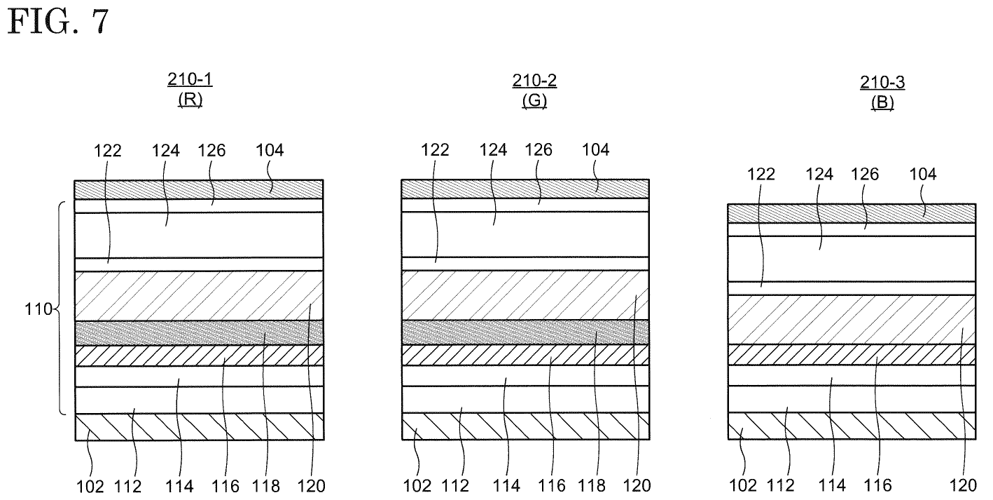

As described above, the light-emitting element 100 is provided in the red-emissive pixel 210-1, while the light-emitting elements without the buffer layer 118 are placed in the green-emissive pixel 210-2 and the blue-emissive pixel 210-3 in the example shown in FIG. 5. The configuration of the display device 200 is not limited to this configuration, and the light-emitting elements 100 may be provided in the red-emissive pixel 210-1 and the green-emissive pixel 210-2, while a light-emitting element different in structure from the light-emitting element 100 may be arranged in the blue-emissive pixel 210-3 as schematically shown in FIG. 7. For example, the light-emitting element provided in the blue-emissive pixel 210-3 may be a light-emitting element without the buffer layer 118 or a light-emitting element including a fluorescent material (which does not exhibit thermally activated delayed fluorescence) in the emission layer 120.

The buffer layers 118 with different structures may be provided separately in the red-emissive pixel 210-1 and the green-emissive pixel 210-2. Alternatively, the buffer layer 118 having the same structure may be provided in the red-emissive pixel 210-1 and the green-emissive pixel 210-2. In this case, the buffer layer 118 is provided to be shared by the red-emissive pixel 210-1 and the green-emissive pixel 210-2 and to be continuous between the red-emissive pixel 210-1 and the green-emissive pixel 210-2. The buffer layer 118 also includes the host material of the emission layer 120 in the red-emissive pixel 210-1 or the host material of the emission layer 120 in the green-emissive pixel 210-2 or consists of the host material of the emission layer 120 in the red-emissive pixel 210-1 or the host material of the emission layer 120 in the green-emissive pixel 210-2.

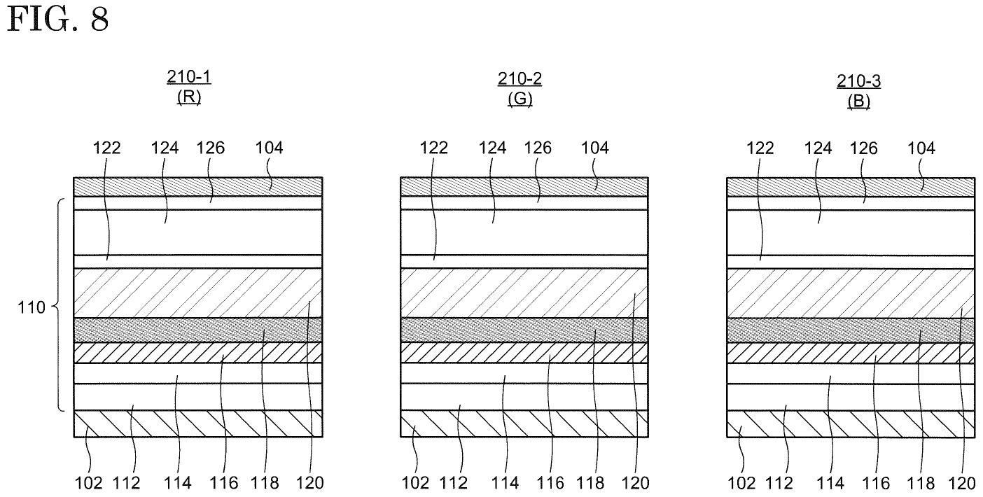

Alternatively, the light-emitting elements 100 may be disposed in all of the pixels 210 as shown in FIG. 8. In this case, the buffer layers 118 with different structures may be provided separately for the red-emissive pixel 210-1, the green-emissive pixel 210-2, and the blue-emissive pixel 210-3. Alternatively, the buffer layer 118 with the same structure may be provided so as to be shared by and continuous in all of the pixels 210. In this case, the buffer layer 118 may contain the host material of the emission layer 120 in the red-emissive pixel 210-1, the host material of the emission layer 120 in the green-emissive pixel 210-2, or the host material in the blue-emissive pixel 210-3 or consists of the host material of the emission layer 120 in the red-emissive pixel 210-1, the host material of the emission layer 120 in the green-emissive pixel 210-2, or the host material of the emission layer 120 in the blue-emissive pixel 210-3.

As described above, the arrangement of the light-emitting element 100 including the buffer layer 118 in the display device 200 allows part of the functional layers such as the electron-blocking layer 116 to be provided so as to be shared by all of the pixels 210. This feature contributes to a reduction in the number of metal masks used in the manufacture of display devices and manufacturing costs thereof due to the reduction in the number of metal masks.

In general, it is relatively difficult to adjust the carrier balance of light-emitting elements containing thermally activated delayed fluorescent materials, and the device structure margin for obtaining an appropriate carrier balance is narrow. In particular, the change in configuration of the electron-blocking layer 116 causes a significant change in the carrier balance, resulting in a significant decrease in various properties such as emission efficiency and driving voltage. However, since the formation of the buffer layer 118 suppresses the influence of the electron-blocking layer 116 on the carrier balance to readily ensure an appropriate carrier balance as proven in the Examples, it is possible to improve or maintain the characteristics of a light-emitting element even if the configuration of the electron-blocking layer 116 changes. Furthermore, the reliability of light-emitting elements is also improved. Therefore, implementation of the embodiment of the present invention enables the production of highly efficient and reliable display devices at a low cost.

### EXAMPLES

A plurality of red-emissive light-emitting elements with different thicknesses of the buffer layer (BL) (Examples) and two red-emissive light-emitting elements without the buffer layer (Comparable Examples) were fabricated. In all of the light-emitting elements, ITO was used as the anode, and a co-deposited film of silver and magnesium was used as the cathode. The size of the emission region was 2.0 mm×2.0 mm. The emission layer contained a host material and a red-emissive thermally activated delayed fluorescent material, and lithium fluoride was used as the electron-injection layer. The structure was identical between all of the light-emitting elements other than the configuration of the electron-blocking layer and the thickness of the buffer layer. The thicknesses of the functional layers structuring the EL layers are shown in Table 1. Here, the light-emitting element in the Comparative Example 1 is an element having an electron-blocking layer optimized for a red-emissive light-emitting element, while the light-emitting elements in the Comparative Example 2 and the Examples are elements having an electron-blocking layer used in light-emitting elements containing a green-emissive thermally activated delayed fluorescent material.

TABLE 1
Thickness of EL layers of light-emitting elements of Examples and Comparable Examples (nm).

| | Hole- | Hole- | Electron- | | | Hole- | Electron- | Electron- |
|---|---|---|---|---|---|---|---|---|
| | injection | transporting | blocking | Buffer | Emission | blocking | transporting | injection |
| Elements | layer | layer | layer | layer | layer | layer | layer | layer |
| Examples | 17 | 60 | 5 | 2.5-10 | 35 | 10 | 20 | 2 |
| Comparable | 17 | 60 | 5 | 0 | 35 | 10 | 20 | 2 |
| Example 1 | | | | | | | | |
| Comparable | 17 | 60 | 5 | 0 | 35 | 10 | 20 | 2 |
| Example 2 | | | | | | | | |

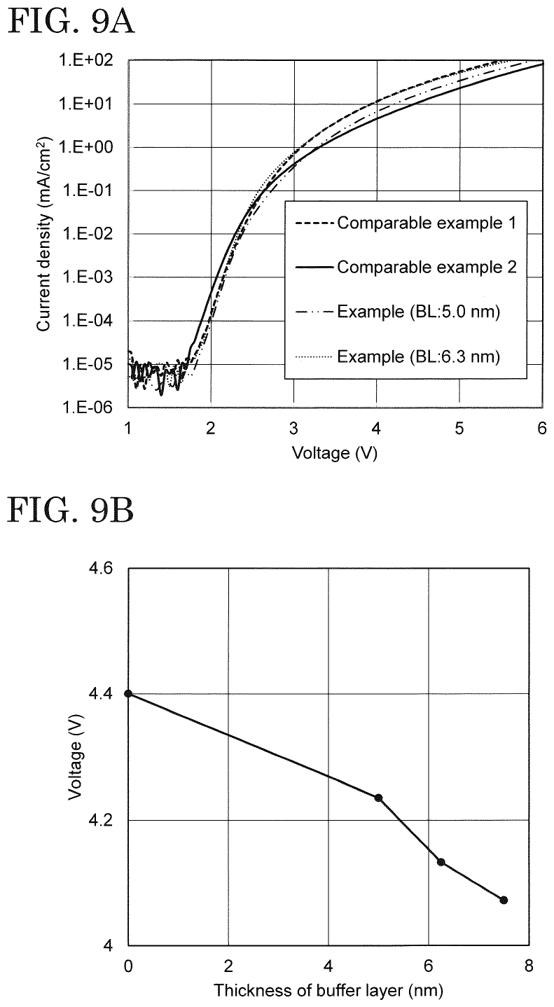

The voltage-current density curves of the fabricated light-emitting elements are shown in FIG. 9A. Comparison of the Comparative Example 1 with the Comparative Example 2 reveals that the voltage-current density curve shifts to the high voltage side when the material in the electron-blocking layer is changed. This result suggests that the change in electron-blocking properties causes an internal electric field due to the carriers (electrons) accumulated at the interface between the electron-blocking layer and the emission layer, leading to a change in the carrier balance and an increase in the driving voltage of the light-emitting element. However, as demonstrated by the light-emitting elements in the Examples, the formation of the buffer layer diffuses the carriers. As a result, it was proven that the voltage-current density curve shifts to the low-voltage side, resulting in a voltage-current density characteristic close to that of Comparative Example 1. These results suggest that the buffer layer improves the carrier balance even if a non-optimized electron-blocking layer is used.

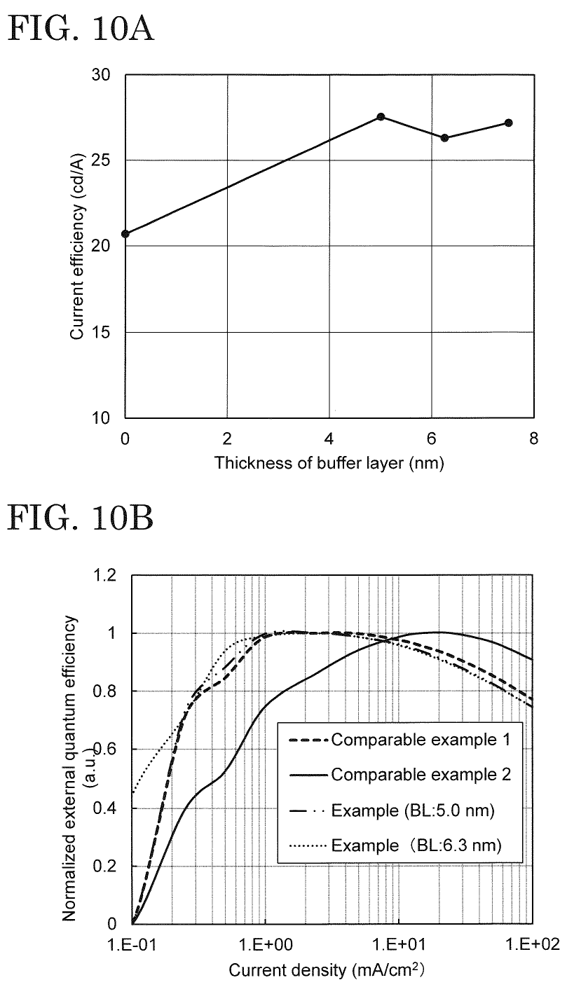

This tendency is also suggested by FIG. 9B and FIG. 10A. FIG. 9B shows a plot of the relationship between the driving voltage and the thickness of the buffer layer of the light-emitting elements of the Comparative Example 2 and the Example 1, indicating that the driving voltage decreases with increasing thickness of the buffer layer. FIG. 10A is a plot showing the relationship between the current efficiency and the thickness of the buffer layer of the light-emitting elements in the Comparative Example 2 and the Example, from which it can be understood that the current efficiency increases as the thickness of the buffer layer increases. It is also suggested that the effects of the buffer layer saturate as the buffer layer thickness approaches 8 nm.

FIG. 10B shows plots of normalized external quantum efficiency versus current density. It is clearly revealed from the comparison between the Comparative Example 1 and the Comparative Example 2 that, when the buffer layer is not optimized, there is a significant decrease in the normalized external quantum efficiency, especially in the low current density region. This result suggests that the carrier balance is greatly disrupted and the contribution of non-radiative recombination increases at a low current density, i.e., at a low driving voltage. Non-radiative recombination corresponds, for example, to the generation of exciplexes and light absorption by polarons. In contrast, it can be understood from FIG. 10B that the plot approaches the plot of the Comparative Example 1 when the buffer layer is provided and the thickness thereof is increased, and that the normalized external quantum efficiency is improved, especially in the low current density region. This result also reveals that, even when a non-optimized electron-blocking layer is used, the formation of the buffer layer suppresses its influence to realize the characteristics similar to or superior to those of the light-emitting element containing an optimized electron-blocking layer.

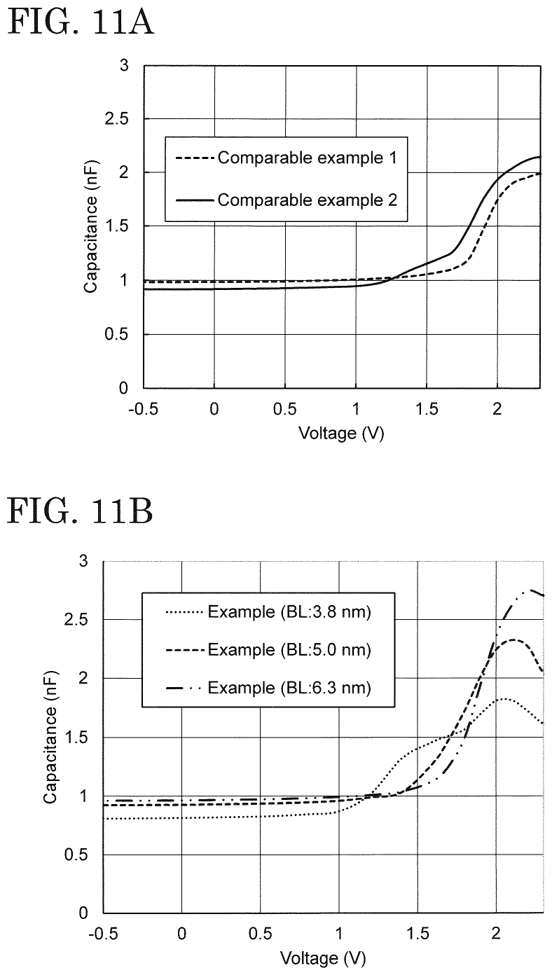

The voltage-capacitance plots of the light-emitting elements of the Comparative Examples 1 and 2 obtained by impedance spectroscopy are shown in FIG. 11A. Comparison of the Comparative Examples 1 and 2 shows that, when the electron-blocking layer is not optimized, the capacitance increases at a low voltage. This result indicates that, when the electron-blocking layer is not optimized, carriers accumulate in the EL layer at an initial driving stage especially at the interface between the electron-blocking layer and the emission layer, resulting in a relatively large internal electric field. In contrast, as can be understood from FIG. 11B, the increase in capacitance in the low-voltage region is eliminated as the thickness of the buffer layer increases in the light-emitting elements of the Examples, showing a tendency to approach the plot of the light-emitting element in the Comparative Example 1. These results also indicate that the buffer layer improves the carrier balance, suppresses the generation of an internal electric field, and lowers the driving voltage. Furthermore, the capacitance in the high-voltage region conversely increases. This result suggests that the carriers used for recombination increase, and the efficiency is improved. In other words, even if the structure of the electron-blocking layer changes, its influence can be suppressed by the buffer layer.

As described above, although extremely high emission efficiency can be obtained in light-emitting elements containing thermally activated delayed fluorescent materials, it is relatively difficult to construct an optimal carrier balance, and the carrier balance is readily affected by the carrier-blocking layer (especially the electron-blocking layer). In contrast, the above results show that the influence of the electron-blocking layer can be suppressed and an appropriate carrier balance can be ensured without significantly compromising reliability by applying the embodiment of the present invention. This means that the electron-blocking layer can also be shared among pixels with different emission colors, thereby reducing the number of metal masks used in the manufacture of display devices including the light-emitting elements containing thermally activated delayed fluorescent materials. Therefore, it can be concluded that the embodiment of the present invention contributes to the production of display devices with high efficiency and reliability at a low cost.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of the light-emitting elements and display devices according to each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A light-emitting element comprising an anode, a cathode, and an electroluminescence layer between the anode and the cathode, the electroluminescence layer comprising:
an electron-blocking layer;
a buffer layer over the electron-blocking layer; and
an emission layer located over the buffer layer and containing a host material and a first emission material exhibiting thermally activated delayed fluorescence, and
the buffer layer contains the host material.

2. The light-emitting element according to claim 1,
wherein an energy difference between a triplet exited state and a singlet excited state of the first emission material is equal to or greater than 5 meV and equal to or less than 20 meV.

3. The light-emitting element according to claim 1,
wherein the emission layer further contains a second emission material, and
an energy level of a singlet excited state of the second emission material is lower than an energy level of a singlet excited state of the first emission material.

4. The light-emitting element according to claim 1,
wherein the buffer layer consists of the host material.

5. The light-emitting element according to claim 1,
wherein the first emission material is red emissive or green emissive.

6. The light-emitting element according to claim 1,
wherein the buffer layer is in contact with the electron-blocking layer and the emission layer.

7. The light-emitting element according to claim 1,
wherein a thickness of the buffer layer is equal to or greater than 2.0 nm and equal to or less than 10.0 nm.

8. A display device comprising a red-emissive pixel, a green-emissive pixel, and a blue-emissive pixel, each comprising:
a pixel electrode;
an electroluminescence layer located over the pixel electrode and including an electron-blocking layer and an emission layer over the electron-blocking layer; and
a cathode over the electroluminescence layer,
wherein the electroluminescence layer of the red-emissive pixel contains a first host material and a first red-emissive emission material exhibiting thermally activated delayed fluorescence,
the red-emissive pixel further includes a first buffer layer containing the first host material between the electron-blocking layer and the emission layer, and
the electron-blocking layer is shared by the red-emissive pixel, the green-emissive pixel, and the blue-emissive pixel and is continuous over the red-emissive pixel, the green-emissive pixel, and the blue-emissive pixel.

9. The display device according to claim 8,
wherein an energy difference between a triplet exited state and a singlet excited state of the first red-emissive emission material is equal to or greater than 5 meV and equal to or less than 20 meV.

10. The display device according to claim 8,
wherein the emission layer of the red-emissive pixel further contains a second red-emissive emission material, and
an energy level of a singlet excited state of the second red-emissive emission material is lower than an energy level of a singlet excited state of the first red-emissive emission material.

11. The display device according to claim 8,
wherein the first buffer layer consists of the first host material.

12. The display device according to claim 8,
wherein the first buffer layer is in contact with the electron-blocking layer and the emission layer in the red-emissive pixel.

13. The display device according to claim 8,
wherein a thickness of the first buffer layer is equal to or greater than 2.0 nm and equal to or less than 10.0 nm.

14. The display device according to claim 8,
wherein the electron-blocking layer is in contact with the emission layer in the green-emissive pixel and the blue-emissive pixel.

15. The display device according to claim 8,
wherein the emission layer of the green-emissive pixel contains a second host material and a first green-emissive emission material exhibiting thermally activated delayed fluorescence, and
the green-emissive pixel includes a second buffer layer containing the second host material between the electron-blocking layer and the emission layer.

16. The display device according to claim 15,
wherein an energy difference between a triplet excited state and a single excited state of the first green-emissive emission material is equal to or greater than 5 meV and equal to or less than 20 meV.

17. The display device according to claim 15,
wherein the emission layer of the green-emissive pixel further contains a second green-emissive emission material, and
an energy level of a single excited state of the second green-emissive emission material is lower than an energy level of a singlet excited state of the first green-emissive emission material.

18. The display device according to claim 15,
wherein the second buffer layer consists of the second host material.

19. The display device according to claim 15,
wherein the second buffer layer is in contact with the electron-blocking layer and the emission layer in the green-emissive pixel.

20. The display device according to claim 15,
wherein a thickness of the second buffer layer is equal to or greater than 2.0 nm and equal to or less than 10.0 nm.
